(19) United States
(12) Patent Application Publication
(10) Pub. No.: US 2016/0108518 A1
(43) Pub. Date: Apr. 21, 2016

(54) THIN FILM MANUFACTURING METHOD AND ATOMIC LAYER DEPOSITION APPARATUS

(71) Applicant: K.C. Tech Co., Ltd., Anseong-si (KR)

(72) Inventors: Sung Hyun PARK, Anseong-si (KR); In Chul SHIN, Seoul (KR); Keun Woo LEE, Hwaseong-si (KR); Kyung Joon KIM, Andong-si (KR)

(21) Appl. No.: 14/834,230

(22) Filed: Aug. 24, 2015

(30) Foreign Application Priority Data
Oct. 20, 2014 (KR) 10-2014-0141940

(51) Int. Cl. C23C 16/34; C23C 16/44; H01L 21/02; C23C 16/455

(52) U.S. Cl. CPC C23C 16/345; C23C 16/45536; C23C 16/45544; C23C 16/4408; H01L 21/02211; H01L 21/0217; H01L 21/02274; H01L 21/0228

(57) ABSTRACT

A method of manufacturing a silicon nitride (Si₃N₄) film at low temperature using an atomic layer deposition (ALD), and an ALD apparatus for the same are disclosed. The method of manufacturing a Si₃N₄ film uses a silicon precursor material including silicon as a source gas, an N₂ gas activated by plasma as a reaction gas, and an N₂ gas as a purge gas, and manufactures a Si₃N₄ film by providing gases in an order of the source gas, the purge gas, the reaction gas, and the purge gas.

### CROSS-REFERENCE TO RELATED APPLICATION

This application claims the priority benefit of Korean Patent Application No. 10-2014-0141940, filed on Oct. 20, 2014, in the Korean Intellectual Property Office, the disclosure of which is incorporated herein by reference.

### BACKGROUND

1. Field of the Invention

Embodiments relate to a method of manufacturing a thin film including a silicon nitride (Si₃N₄) film using an atomic layer deposition (ALD) and an ALD apparatus for the same.

2. Description of the Related Art

In general, a physical vapor deposition (PVD) using physical collisions such as sputtering, a chemical vapor deposition (CVD) using chemical reactions, and the like are used to deposit a thin film with a predetermined thickness on a substrate, such as a semiconductor substrate and a glass, for example. Recently, as a design rule of a semiconductor device becomes rapidly minute, a thin film having a micropattern is required, and a step of a region in which the thin film is formed significantly increased. With such trend, use of an atomic layer deposition (ALD) capable of manufacturing a considerably uniform micropattern with an atomic layer thickness and having excellent step coverage is increasing.

In terms of using chemical reactions between gas molecules included in a deposition gas including a source material, the ALD process is similar to a general CVD. However, unlike the typical CVD that injects a plurality of deposition gases simultaneously into a process chamber and deposits a generated reaction product on a substrate, the ALD process injects a gas including a single source material into a chamber, chemisorbs the injected gas on a heated substrate, and then injects a gas including another source material into the chamber, thereby depositing a product generated by chemical reactions between the source materials on a surface of the substrate. The ALD process has an extremely excellent step coverage property and an advantage of being capable of manufacturing a pure thin film having relatively low impurity content and thus, is currently widely used.

In a case of the existing ALD process, when a source material with a relatively low reactivity is used or when temperature is relatively low, a quality of a thin film may decrease. For example, in the past, a silicon nitride (Si3N4) film was manufactured using a low-pressure CVD process at high temperature of over 600° C. However, due to a miniaturization of a semiconductor device, a process at relatively low temperature, and the like, a specific process may not be performed at the abovementioned temperature and thus is to be performed at lower temperature. However, at such relatively low temperature, a Si₃N₄ film may not be manufactured or the quality of the thin film may sharply decrease. In addition, manufacturing of a Si₃N₄ film using the ALD process may be hindered by a relatively low reactivity.

### SUMMARY

Embodiments provide a method of manufacturing a high-quality silicon nitride (Si₃N₄) film at low temperature and an atomic layer deposition (ALD) apparatus for the same.

The technical goals of the present disclosure are not limited to the above-mentioned goal and further goals not described above will be clearly understood by those skilled in the art.

According to embodiments, there is provided a thin film manufacturing method of manufacturing a silicon nitride (Si₃N₄) film by providing gases in an order of a source gas, a purge gas, a reaction gas, and the purge gas. A silicon precursor material including silicon is used as the source gas, a nitrogen (N₂) gas activated by plasma is used as the reaction gas, and an N₂ gas is used as the purge gas.

A silylamine-based material may be used as the source gas. Here, the source gas may have a structure in which three silicon (Si) atoms are arranged around an -Amine (N) group, at least one of the three Si atoms includes at least one -Amine group, and the -Amine group includes at least one -Ethyl (C₂H₅) group or at least one -Methyl (CH₃) group. For example, one of Bis[(dimethylamino)methylsilyl](trimethylsilyl)amine, Bis[(diethylamino)dimethylsilyl](trimethylsilyl)amine, and Tris[(diethylamino)dimethylsilyl]amine may be used as the source gas.

The Si₃N₄ film may be manufactured at temperature in a range of 200 to 350° C. The process may be performed by spraying the source gas, the purge gas, the reaction gas, and the purge gas consecutively.

According to embodiments, there is also provided an ALD apparatus including a process chamber, a substrate supporter provided in the process chamber, the substrate supporter on which a plurality of substrates is disposed, and a gas sprayer provided over the substrate supporter in the process chamber to spray a source gas, a reaction gas, and a purge gas onto the plurality of substrates consecutively. A silicon precursor material including silicon is used as the source gas, an N₂ gas activated by plasma is used as the reaction gas, an N₂ gas is used as the purge gas, and the ALD apparatus manufactures a Si₃N₄ film by providing gases in an order of the source gas, the purge gas, the reaction gas, and the purge gas.

A silylamine-based material may be used as the source gas. Here, the source gas may have a structure in which three Si atoms are arranged around an -Amine (N) group, at least one of the three Si atoms includes at least one -Amine group, and the -Amine group includes at least one -Ethyl (C₂H₅) group or at least one -Methyl (CH₃) group. For example, one of Bis[(dimethylamino)methylsilyl](trimethylsilyl)amine, Bis[(diethylamino)dimethylsilyl](trimethylsilyl)amine, and Tris[(diethylamino)dimethylsilyl]amine may be used as the source gas.

The ALD apparatus further includes a plasma generator provided in the gas sprayer to activate the reaction gas by plasma. For example, the plasma generator may generate plasma using one of remote plasma, capacitively coupled plasma (CCP), and inductively coupled plasma (ICP).

### BRIEF DESCRIPTION OF THE DRAWINGS

These and/or other aspects, features, and advantages of the disclosure will become apparent and more readily appreciated from the following description of embodiments, taken in conjunction with the accompanying drawings of which:

FIG. 1 is a mimetic diagram illustrating an atomic layer deposition (ALD) apparatus according to an embodiment;

FIG. 2 is a diagram illustrating a molecular structure of Bis[(dimethylamino)methylsilyl](trimethylsilyl)amine;

FIG. 3 is a diagram illustrating a molecular structure of Bis[(diethylamino)dimethylsilyl](trimethylsilyl)amine;

FIG. 4 is a graph illustrating a comparison of purge gases in terms of growth rate per cycle (GPC) and wet etch rate (WER) in a thin film manufacturing method according to an embodiment;

FIG. 5 is a graph illustrating a comparison of reaction gases in terms of GPC and WER in a thin film manufacturing method according to an embodiment; and

FIG. 6 is a graph illustrating a comparison of source gases in terms of GPC, WER, and uniformity in a thin film manufacturing method according to an embodiment.

### DETAILED DESCRIPTION

Hereinafter, embodiments of the present disclosure will be described in detail with reference to the accompanying drawings, wherein like reference numerals refer to the like elements throughout. However, the present disclosure is not limited to the embodiments described herein. When it is determined detailed description related to a known function or configuration which may render the purpose of the present disclosure unnecessarily ambiguous in describing the present disclosure, the detailed description will be omitted here.

In addition, terms such as first, second, A, B, (a), (b), and the like may be used herein to describe components. Each of these terminologies is not used to define an essence, order or sequence of a corresponding component but used merely to distinguish the corresponding component from other component(s). It should be noted that if it is described in the specification that one component is “connected”, “coupled”, or “joined” to another component, a third component may be “connected”, “coupled”, and “joined” between the first and second components, although the first component may be directly connected, coupled or joined to the second component.

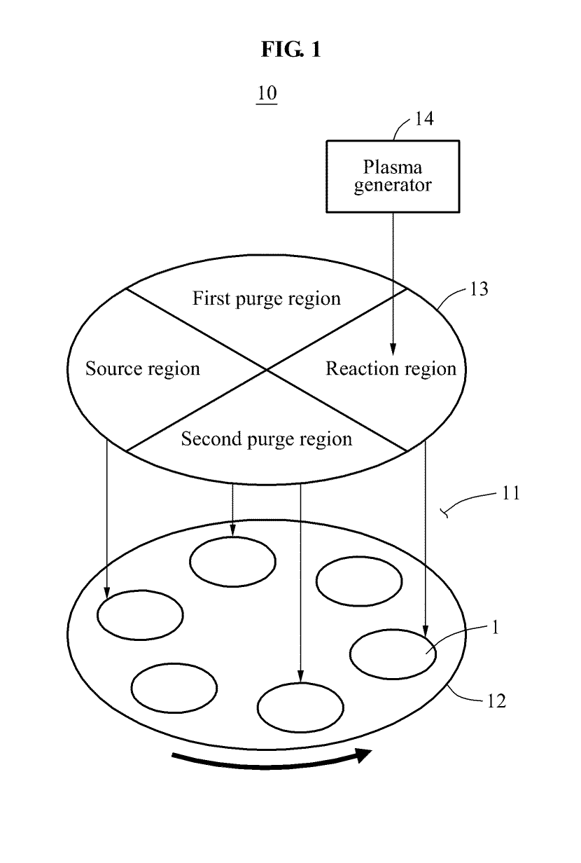

Hereinafter, an atomic layer deposition (ALD) apparatus 10 and a thin film manufacturing method using the same according to embodiments will be described in detail with reference to FIGS. 1 through 6.

A thin film manufacturing method according to an embodiment manufactures a silicon nitride (Si₃N₄) film using an ALD process. First, an example of the ALD apparatus 10 for manufacturing a thin film according to the present embodiment will be described. The ALD apparatus 10 according to the present embodiment may be a semi-batch type ALD apparatus that performs a deposition process with respect to a plurality of substrates 1 simultaneously.

In the present embodiment, a substrate 1 to be deposited may be a silicon wafer. However, the substrate 1 is not limited thereto and may be a transparent substrate including glass to be used for a flat panel display, such as a liquid crystal display (LCD) and a plasma display panel (PDP), for example. In addition, the shape and the size of the substrate 1 is not limited by the drawings. The substrate 1 may substantially have various shapes, for example, a circular shape and a rectangular shape, and various sizes.

FIG. 1 is a mimetic diagram illustrating the ALD apparatus 10 according to an embodiment.

Referring to FIG. 1, the ALD apparatus 10 includes a process chamber 11, a substrate supporter 12 on which the plurality of substrates 1 is disposed, and a gas sprayer 13 configured to spray gases onto the substrates 1. Detailed technical configurations of the process chamber 11, the substrate supporter 12, the gas sprayer 13, and the like constituting the ALD apparatus 10 may be understood from known arts and thus, detailed descriptions will be omitted herein and major constituent elements will be described in brief.

The gas sprayer 13 sprays a source gas, a reaction gas, and a purge gas toward an inner portion of the process chamber 11. The gas sprayer 13 is divided into a plurality of regions from which the respective gases are sprayed. In this example, the gases are sprayed consecutively from the respective regions of the gas sprayer 13. For example, the gas sprayer 13 may include four regions, in detail, a region from which the source gas is sprayed, hereinafter referred to as a “source region”, a region from which the reaction gas is sprayed, hereinafter referred to as a “reaction region”, and two regions disposed therebetween and from which the purge gas is sprayed, hereinafter referred to as “first and second purge regions”. However, the embodiment is not limited by the drawings and the gas sprayer 13 may be divided into four or more regions.

Further, a plasma generator 14 may be provided in the gas sprayer 13 to activate the reaction gas by plasma. For example, the plasma generator 14 may be provided in the reaction region of the gas sprayer 13, or may be provided on a flow path of the reaction gas that flows in the reaction region. In addition, the plasma generator 14 may turn the reaction gas into plasma using remote plasma, turn the reaction gas into plasma in the inner portion of the process chamber 11 using capacitively coupled plasma (CCP), or turn the reaction gas into plasma using inductively coupled plasma (ICP).

The plurality of substrates 1 is horizontally and radially disposed on the substrate supporter 12. When the substrate supporter 12 rotates, the substrates 1 disposed on a surface of the substrate supporter 12 also rotate, thereby sequentially passing through the source region, the first purge region, the reaction region, and the second purge region. When the substrates 1 rotate, a source material of the source gas reacts with a source material of the reaction gas on the substrates 1, whereby a thin film is manufactured.

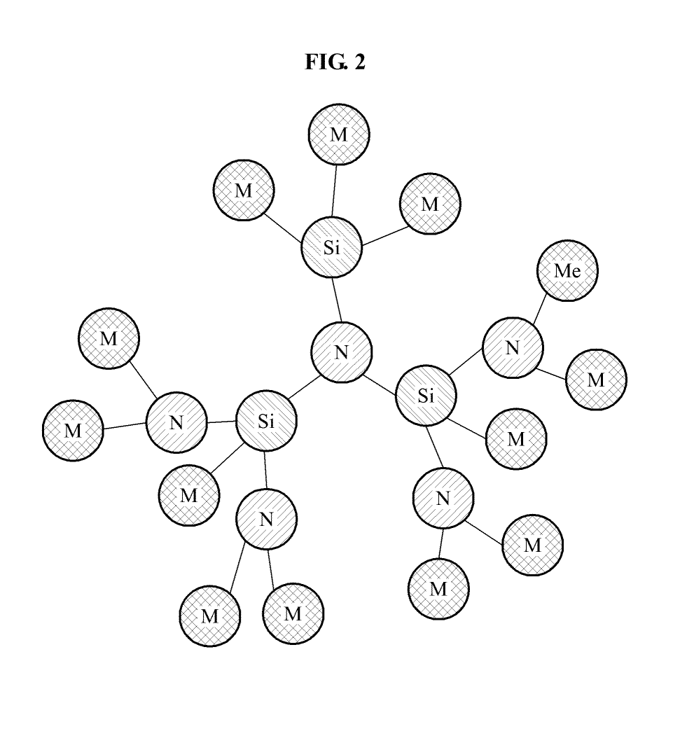

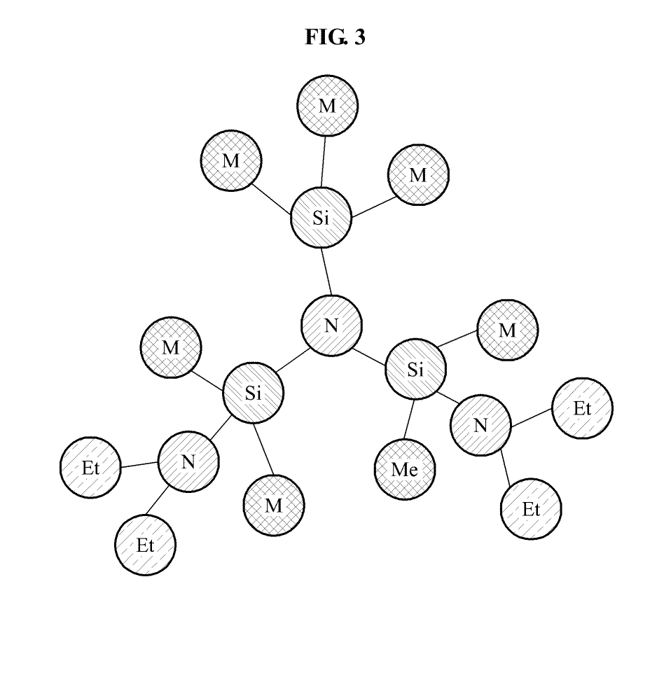

A high-quality Si₃N₄ film may be manufactured at low temperature using a silylamine-based material as the source gas, a nitrogen (N₂) gas activated by plasma as the reaction gas, and an N₂ gas as the purge gas. In detail, the source gas may have a structure in which three silicon (Si) atoms are arranged around an -Amine (N) group, the three Si atoms are bonded to the central -Amine group, at least one of the three Si atoms includes at least one -Amine group, and the -Amine group includes at least one -Ethyl (C₂H₅) group or at least one -Methyl (CH₃) group. For example, the source gas may include Bis[(dimethylamino)methylsilyl](trimethylsilyl)amine, Bis[(diethylamino)dimethylsilyl](trimethylsilyl)amine, Tris[(diethylamino)dimethylsilyl]amine, and the like. Here, FIG. 2 is a diagram illustrating a molecular structure of BisRdimethylamino)methylsilylKtrimethylsilyl)amine, and FIG. 3 is a diagram illustrating a molecular structure of Bis[(diethylamino)dimethylsilyl](trimethylsilyl)amine .

According to the present embodiment, the high-quality Si₃N₄ layer may be manufactured at low temperature in a range of 200 to 350° C. using the semi-batch type ALD apparatus 10.

A silicon-containing gas of a metal halide or metal organic form is used as the source gas, and the Si₃N₄ film may be manufactured using a combination of gases such as N₂, H₂, NH₃, Ar, He, and the like. However, in a case of using such a source gas, an activated reaction gas, that is, NH3, may be used as a precursor including at least one C1, in particular, among metal halide-based gases. In a case in which a Si₃N₄ film is manufactured as described above, a low-quality thin film is manufactured and a C1 impurity may be included in the thin film. Further, in a case of depositing the thin film using nitridant activated by plasma, a relatively large amount of time is required and thus, commercialization thereof is difficult. In addition, due to a relatively high probability of gases being mixed in a chamber of a semi-batch type ALD apparatus that performs a process while rotating a plurality of substrates, types of gases to be sprayed from respective regions may be restricted, and in particular, the gases are used restrictively for a silicone precursor.

A thin film manufacturing method according to an embodiment may manufacture a Si₃N₄ film using a silicon precursor material including silicon, in detail, a silylamine-based material as a source gas, an N₂ gas activated by plasma as a reaction gas, and an N₂ gas as a purge gas. Further, the thin film manufacturing method may manufacture the Si₃N₄ film using a semi-batch type ALD apparatus.

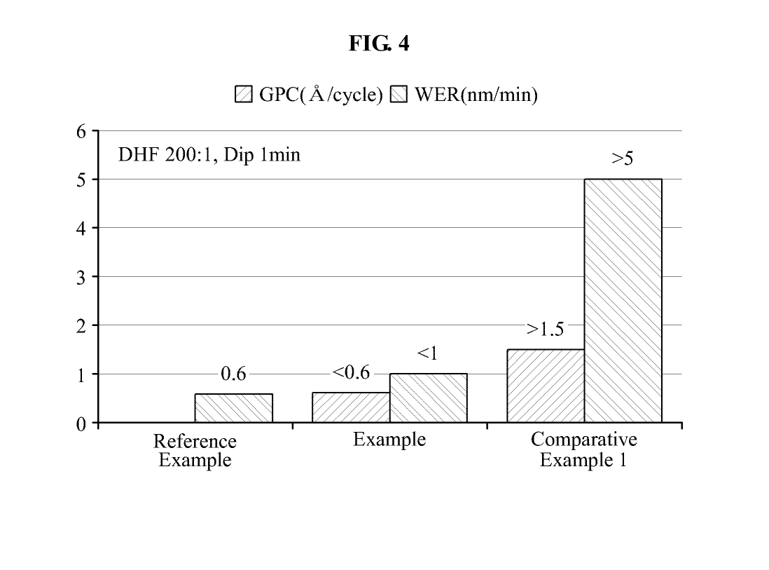

To verify a quality of a thin film manufactured according to the present embodiment, Si₃N₄ films were manufactured by varying a purge gas, a reaction gas, and a source gas under the same conditions as follows, and growth rates per cycle (GPCs) and wet etch rates (WERs) of the respective cases were measured and compared. The results are shown in FIGS. 4 through 6.

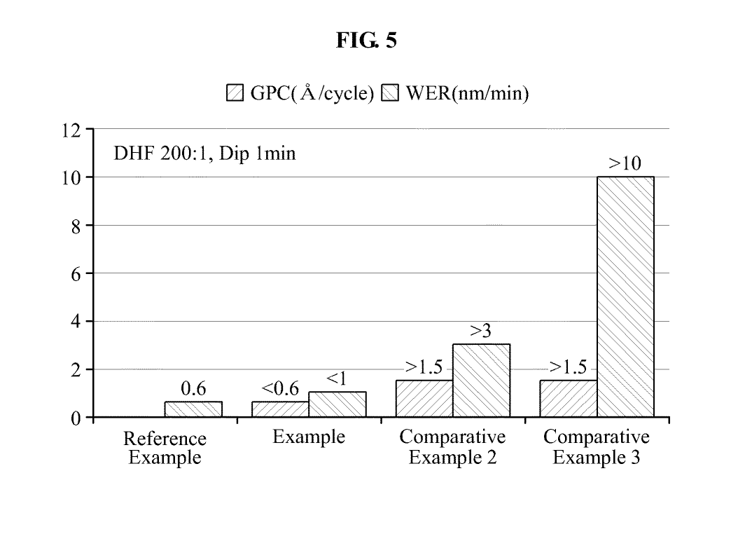

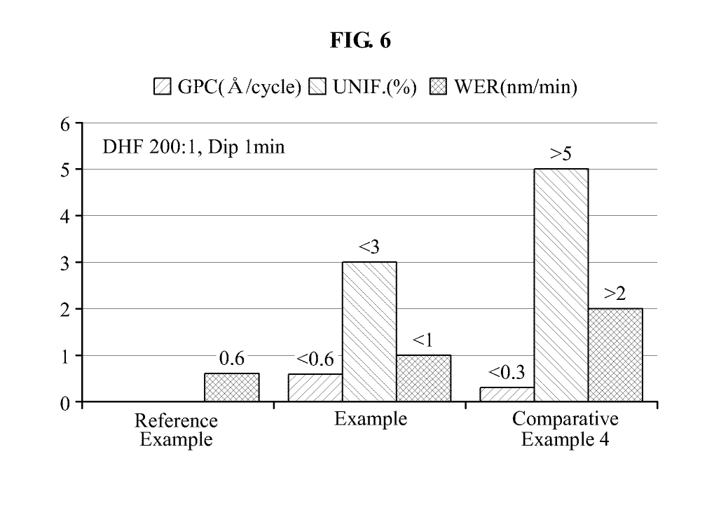

For reference, FIG. 4 is a graph illustrating a comparison of purge gases in terms of GPC and WER in a thin film manufacturing method according to an embodiment, FIG. 5 is a graph illustrating a comparison of reaction gases in terms of GPC and WER in a thin film manufacturing method according to an embodiment, and FIG. 6 is a graph illustrating a comparison of source gases in terms of GPC, WER, and uniformity in a thin film manufacturing method according to an embodiment. In FIGS. 4 through 6, a Si₃N₄ film manufactured at temperature of 700° C. by a low-pressure chemical vapor deposition (CVD) apparatus was used as Reference Example which is a reference to be compared to.

Referring to FIG. 4, a Si₃N₄ film was manufactured by the aforementioned semi-batch type ALD apparatus 10 using a silylamine-based gas as a source gas, an N₂ gas activated as plasma as a reaction gas, and an N₂ gas and an Ar gas as purge gases, respectively.

In Example in which the N₂ gas was used as the purge gas, the GPC was saturated at 0.6 angstroms per cycle (A/cycle), and the WER was at a level of under 1 nanometer per minute (nm/min). When compared to Reference Example in which the Si₃N₄ film was manufactured at temperature of 700° C. by the low-pressure CVD apparatus, it can be learned that a similar level of WER was measured. Meanwhile, in Comparative Example 1 in which the Ar gas was used as the purge gas, the GPC was a value of over 1.5 Å/cycle, and the WER was a value of over 5 nm/min. In the case of Comparative Example 1, it was verified that a CVD-like ALD reaction occurred. For reference, although the CVD-like ALD includes a purging process similar to an ALD process order, a thin film is manufactured at a point in time at which a source gas and a reaction gas simultaneously resolve and react. When compared to a typical ALD process, the manufactured thin film is relatively thick. In the case of ALD, a thin film with a thickness thinner than a monatomic layer per 1 cycle is manufactured, whereas in the case of CVD-like ALD, a thin film with a thickness thicker than a monatomic layer per 1 cycle.

Referring to FIG. 5, a Si₃N₄ film was manufactured by the aforementioned semi-batch type ALD apparatus using a silylamine-based gas as a source gas, and an N₂ gas as a purge gas. However, an N₂ gas activated by plasma was used as a reaction gas in Example, a gas mixture of N₂ and Ar was used as the reaction gas in Comparative Example 2, and a gas including H was used as the reaction gas in Comparative Example 3.

In the case of Example, the GPC was saturated at 0.6 Å/cycle, and the WER was at a level of under 1 nm/min. Thus, it can be verified that the WER is similar to that of Reference Example. Meanwhile, in the case of Comparative Example 2 in which the gas mixture of N₂ and Ar was used as the reaction gas, the GPC was a value of over 1.5 Å/cycle, and the WER was a value of over 3 nm/min. Thus, it was verified that a CVD-like ALD reaction occurred. In the case of Comparative Example 3 in which the gas including H was used as the reaction gas, the GPC was a value of over 1.5 Å/cycle, and the WER was a value of over 10 nm/min. Thus, it was verified that a Si₃N₄ film including an excessive amount of H was manufactured. For reference, a Si₃N₄ film is manufactured mainly using a combination of Si and N. A thin film including an excessive amount of H has a Si—H bonding structure and thus, forms a site to which Si may not bond, for example, a dangling bond of a Si— form. Accordingly, the thin film is not dense and an H site increases a reactivity to a F-based etching chemical, which results in an increase in an etch rate.

Referring to FIG. 6, a Si₃N₄ film was manufactured by the aforementioned semi-batch type ALD apparatus using an N₂ gas activated by plasma as a reaction gas, and an N₂ gas as a purge gas. Here, a silylamine-based Si precursor was used as a source gas in Example, and another Si precursor was used as the source gas in Comparative Example 4.

In the case of Example, the GPC was saturated at 0.6 Å/cycle, the thickness uniformity was under 3% of a 300-mm wafer standard, and the WER was a level of under 1 nm/min, which is similar to that of Reference Example. Meanwhile, in the case of

Comparative Example 4 in which the other Si precursor was used, the GPC was a value of over 0.3 Å/cycle, the thickness uniformity was over 5% of the 300-mm wafer standard, and the WER was a value of over 2 nm/min. Thus, when compared to Example, it was verified that the quality of the thin film deteriorated.

As described above, according to embodiments, a Si₃N₄ may be manufactured by a semi-batch type ALD apparatus using a silylamine-based Si precursor as a source gas, an N₂ gas activated as plasma as a reaction gas, and an N₂ gas as a purge gas, and the Si₃N₄ film may be manufactured at low temperature in a range of 200 to 350° C. Further, a thin film having a WER property similar to that of the Si₃N₄ film manufactured at temperature of 700° C. by the low-pressure CVD apparatus, a GPC property and uniformity suitable for an ALD reaction, rather than a CVD-like ALD reaction, and an excellent quality may be manufactured, whereby a quality of a semiconductor device may increase.

Various embodiments may achieve at least one of the following effects.

As described above, according to the embodiments, a high-quality Si₃N₄ film may be manufactured at low temperature using an N₂ gas activated by plasma.

Further, the Si₃N₄ film may be manufactured by a semi-batch type ALD apparatus.

In addition, a through-put may increase.

A number of embodiments have been described above. Nevertheless, it should be understood that various modifications may be made to these embodiments. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A thin film manufacturing method of manufacturing a silicon nitride (Si₃N₄) film by providing gases in an order of a source gas, a purge gas, a reaction gas, and the purge gas,
wherein a silicon precursor material comprising silicon is used as the source gas, a nitrogen (N₂) gas activated by plasma is used as the reaction gas, and an N₂ gas is used as the purge gas.

2. The thin film manufacturing method of claim 1, wherein a silylamine-based material is used as the source gas.

3. The thin film manufacturing method of claim 2, wherein the source gas comprises three silicon (Si) atoms arranged around an -Amine (N) group, at least one of the three Si atoms comprises at least one -Amine group, and the -Amine group comprises at least one -Ethyl (C₂H₅) group or at least one -Methyl (CH₃) group.

4. The thin film manufacturing method of claim 2, wherein a material selected from the group consisting of Bis[(dimethylamino)methylsilyl](trimethylsilyl)amine, Bis[(diethylamino)dimethylsilyl](trimethylsilyl)amine, and Tris[(diethylamino)dimethylsilyl]amine is used as the source gas.

5. The thin film manufacturing method of claim 1, wherein the Si₃N₄ film is manufactured at temperature in a range of 200 to 350° C.

6. The thin film manufacturing method of claim 1, wherein the source gas, the purge gas, the reaction gas, and the purge gas are sprayed consecutively.

7. An atomic layer deposition (ALD) apparatus comprising:
a process chamber;
a substrate supporter provided in the process chamber, the substrate supporter on which a plurality of substrates is disposed; and
a gas sprayer provided over the substrate supporter in the process chamber to spray a source gas, a reaction gas, and a purge gas onto the plurality of substrates consecutively,
wherein a silicon precursor material comprising silicon is used as the source gas, a nitrogen (N₂) gas activated by plasma is used as the reaction gas, an N₂ gas is used as the purge gas, and the ALD apparatus manufactures a silicon nitride (Si₃N₄) film by providing gases in an order of the source gas, the purge gas, the reaction gas, and the purge gas.

8. The ALD apparatus of claim 7, wherein a silylamine-based material is used as the source gas.

9. The ALD apparatus of claim 8, wherein the source gas comprises three silicon (Si) atoms arranged around an -Amine (N) group, at least one of the three Si atoms comprises at least one -Amine group, and the -Amine group comprises at least one -Ethyl (C₂H₅) group or at least one -Methyl (CH₃) group.

10. The ALD apparatus of claim 8, wherein a material selected from the group consisting of Bis[(dimethylamino)methylsilyl](trimethylsilyl)amine, Bis[(diethylamino)dimethylsilyl](trimethylsilyl)amine, and Tris[(diethylamino)dimethylsilyl]amine is used as the source gas.

11. The ALD apparatus of claim 7, further comprising:
a plasma generator provided in the gas sprayer to activate the reaction gas by plasma.

12. The ALD apparatus of claim 11, wherein the plasma generator generates plasma using one of remote plasma, capacitively coupled plasma (CCP), and inductively coupled plasma (ICP).
